(19) United States
(12) Patent Application Publication
(10) Pub. No.: US 2009/0101395 A1
(43) Pub. Date: Apr. 23, 2009

(54) PRINTED WIRING BOARD AND ELECTRONIC APPARATUS

(75) Inventors: Kazuhito HORIKIRI, Tokyo (JP); Kiyokazu ISHIZAKI, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/187,185

(22) Filed: Aug. 6, 2008

(30) Foreign Application Priority Data
Oct. 23, 2007 (JP) 2007-275392

(51) Int. Cl. H05K 1/03

(52) U.S. Cl. 174/255

(57) ABSTRACT

A printed wiring board includes: a component mounting region; a plurality of electrode pads arranged at a peripheral edge portion of the component mounting region; a solder resist film that coats the component mounting region; and a plurality of solder bonding faces arranged at a region surrounded by the plurality of electrode pads. The solder resist film and the plurality of solder bonding faces form an island-shaped pattern such that the plurality of solder bonding faces are isolated with each other by the solder resist film.

### CROSS-REFERENCE TO RELATED APPLICATIONS

This application is based upon and claims the benefit of priority from Japanese Patent Application No. 2007-275392, filed Oct. 23, 2007, the entire contents of which are incorporated herein by reference.

### BACKGROUND

1. Field

The present invention relates to a printed wiring board and an electronic apparatus that install an electronic component having external electrodes and a die pattern at a bottom face thereof.

2. Description of Related Art

In an electronic component having external electrodes and a die pattern (thermal pad) for the purpose of heat radiation at a bottom face thereof, such as a semiconductor component of a quad flat non-leaded package (QFN), or a land grid array (LGA), a heat radiating path (heat conducting path) for outwardly radiating heat generated at the semiconductor component is formed by solder-bonding the die pattern to a pattern provided at a printed wiring board. The solder-bonding of the patterns might raise the following problems: That is, in the soldering bonding of the faces of the patterns, when the amount of supplied solder is excessively large, the component may be floated up so that a height of the mounted component becomes large. At this occasion, the amount of supplied solder to a surrounding electrode becomes deficient for the mounted height, thereby causing a drawback of an open failure. In contrast, when the amount of supplied solder is excessively small, the component may be adsorbed by the spread solder, or may be inclined by the nonuniformly spread solder, so that the height of the mounted component becomes small. At this occasion, the amount of supplied solder to the surrounding electrodes becomes excessive for the mounted height to crush a solder bump so that a short circuit failure or a solder ball may occur. In view of these, based on an actual fabrication experience, the amount of solder for bonding the patterns is determined by an opening diameter of a metal mask for printing and coating a solder (cream solder) to the solder bonding portion in order to reduce the defectives.

As a technology of forming a heat conducting path at a bottom face of a semiconductor component, there is a heat radiating technology of providing a heat radiating pad inside of a face of a printed wiring board where a semiconductor component is to be mounted, providing a heat conducting path penetrating the printed wiring board, and radiating heat received from the heat radiating pad outwardly through the heat conducting path. According to the heat radiating technology, a silver paste is filled in an opening portion penetrating the printed wiring board to form the heat conducting path, while needing an original fabrication technology that is not present in an ordinary board fabrication. See JP-A-2003-282778.

When the heat conducting path is formed by solder-bonding the patterns at the bottom face of the mounted part as described above, it is necessary to reduce failures such as no connection of the electrodes caused by the excessively large amount of supplied solder, and short circuit of the electrodes caused by the excessively small amount of supplied solder.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a plane view showing a configuration of a printed wiring board according to a first embodiment;

FIG. 2 is a plane view showing a configuration of an electronic component that is to be mounted on the printed wiring board according to the first embodiment;

FIG. 3 is a side sectional view showing a configuration of the printed wiring board according to the first embodiment;

FIG. 4 is a view showing a divided width and a divided opening diameter to explain a configuration of arranging a solder bonding face portion of the printed wiring board according to the first embodiment;

FIG. 5 is a plane view showing a printed wiring board according to a second embodiment;

FIG. 6 is a plane view showing a printed wiring board according to a third embodiment; and

FIGS. 7A and 7B illustrate a perspective view and a side sectional view showing a configuration of an electronic apparatus according to a fourth embodiment.

### DETAILED DESCRIPTION

Various embodiments according to the invention will be described hereinafter with reference to the accompanying drawings. In general, according to one embodiment of the invention, a printed wiring board includes: a component mounting region; a plurality of electrode pads arranged at a peripheral edge portion of the component mounting region; a solder resist film that coats the component mounting region; and a plurality of solder bonding faces arranged at a region surrounded by the plurality of electrode pads; wherein the solder resist film and the plurality of solder bonding faces form an island-shaped pattern such that the plurality of solder bonding faces are isolated with each other by the solder resist film.

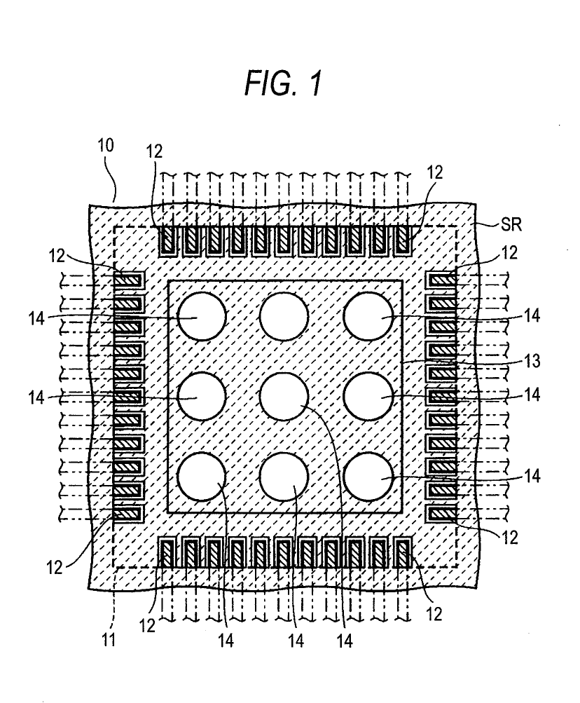

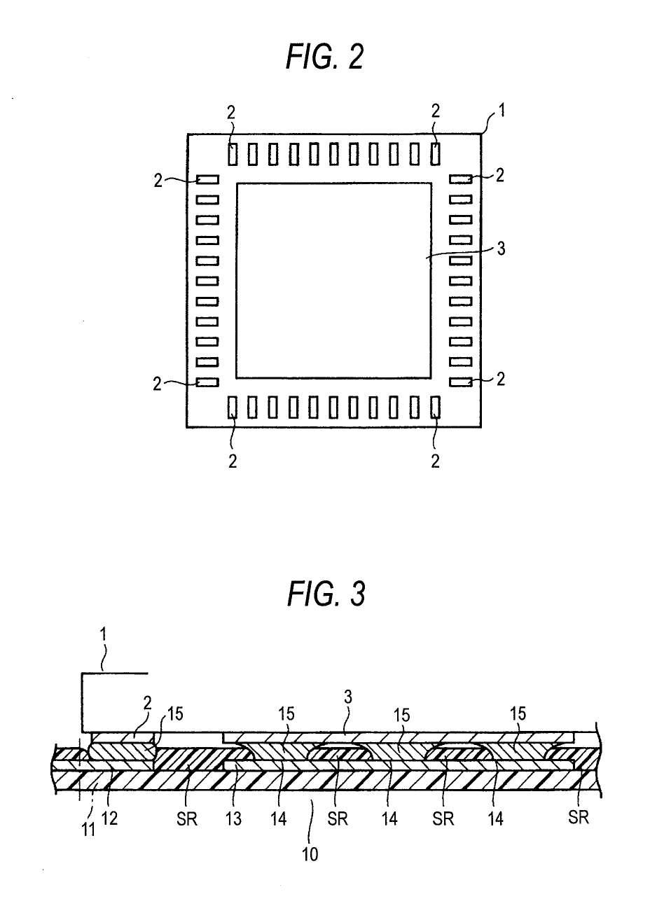

According to a first embodiment, FIG. 1 shows a configuration of a printed wiring board. FIG. 2 shows a configuration of an electronic component mounted on the printed wiring board shown in FIG. 1. The electronic component mounted on the printed wiring board according to the first embodiment of the invention is a semiconductor component, such as a quad flat non-leaded package (QFN)), or a land grid array (LGA), including external electrodes at a peripheral edge portion of a bottom face and including a die pattern (thermal pad) for the purpose of radiating heat at a center portion of the bottom face surrounded by the external electrode. A QFN is taken as an example in the embodiment shown in FIG. 1 and FIG. 2. FIG. 1 shows a configuration of a component mounting region on which the semiconductor component is mounted. FIG. 2 shows the configuration of the semiconductor component (QFN) mounted on the component mounting region shown in FIG. 1 by the use of solder-bonding. FIG. 3 shows a state of solder-bonding the semiconductor component 1 shown in FIG. 2 on a printed wiring board 10 shown in FIG. 1, that is, a state of solder-bonding in a component mounting region 11 where the semiconductor component 1 is mounted on the printed wiring board 10.

As shown in FIG. 1, the printed wiring board 10 according to the first embodiment includes a plurality of electrode pads 12, 12, . . . arranged at a peripheral edge portion of the component mounting region 11, an island shaped pattern (thermal land) 13 provided at a region surrounded by the electrode pads 12, 12, . . . inside the component mounting region 11, and a plurality of solder bonding face portions 14, 14, . . . by partitioning the region by a coating of a solder resist (SR) in the island shaped pattern 13.

The island shaped pattern 13 is made from a copper foil similar to the electrode pads 12, 12, . . . , and is collectively formed by an etching procedure or the like at the same time when the pattern including the electrode pads 12, 12, . . . is formed.

As shown in FIG. 2, the semiconductor component (QFN) 1 mounted on the part mounting region 11 includes external electrodes 2, 2, . . . at a peripheral edge of a bottom face thereof. The semiconductor component also includes a die pattern (thermal pad) 3 for the purpose of heat radiation at a center portion of the bottom face surrounded by the external electrodes 2, 2, . . . . Further, the die pattern 3 may be either of a ground pattern forming an electrode on a ground side, or a floating pattern which is not connected to a circuit.

The electrode pads 12, 12, . . . are arranged so as to correspond to the external electrodes 2, 2, . . . at the peripheral edge portion of the bottom face of the semiconductor component 1 mounted on the part mounting region 11, the island shaped pattern 13 is provided correspondingly to the single die pattern 3 formed at the center portion of the bottom face of the semiconductor component 1. The solder bonding face portions 14, 14, . . . are uniformly arranged with respect to the die pattern 3 that forms a heat radiating path of the semiconductor component 1.

As shown in FIG. 3, the solder bonding face portions 14, 14, . . . are formed in opening portions in the island shaped pattern, on which the solder resist (SR) coating are not formed. The amount of solder 15 bonded to the die pattern 3 is adjusted (rectified) by an opening area of the opening portions.

According to the first embodiment, nine pieces of the circular solder bonding face portions 14, 14, . . . are arranged at constant intervals in a form of matrix, thereby forming a partitioned arrangement.

The solder resist (SR) defining the nine pieces of circular solder bonding face portions 14, 14, . . . is coated simultaneously and collectively at a resist coating procedure for forming the solder resist film on the solder bonding portion including the electrode pads 12, 12, . . . and its surroundings. It is not necessary to perform a procedure of the solder resist coating to only form the solder bonding face portions 14, 14, . . . .

As described above, the plurality of solder bonding face portions 14, 14, . . . isolated by the solder resist (SR) in the face of the island shaped pattern 13, the amount of the solder 15 bonded to the die pattern 3 is adjusted (rectified) into an appropriate amount.

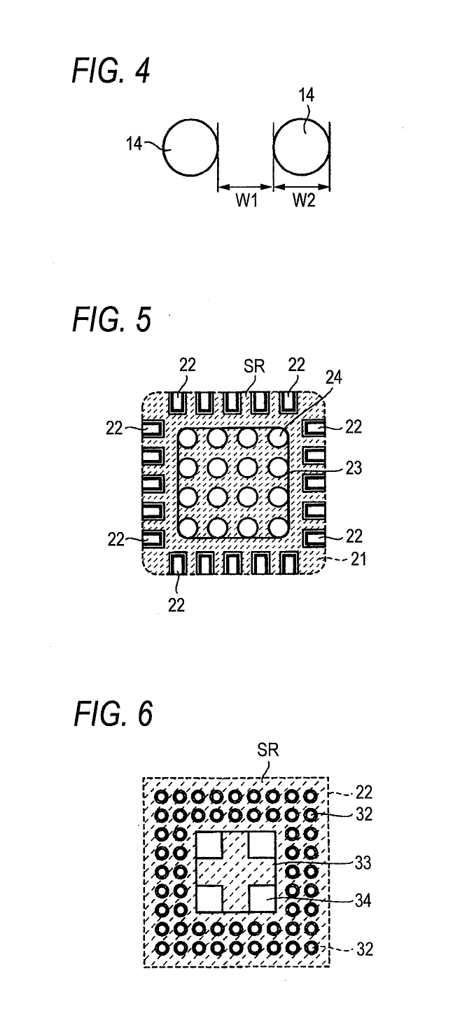

The solder bonding face portions 14, 14, . . . realizes can carry out further highly reliable solder mounting at the component mounting region 11 without interposing a special fabricating procedure by determining a divided width (W1) and a divided opening diameter (W2) of the solder bonding face portions 14, 14, . . . using the solder resist (SR) shown in FIG. 4 in consideration of a metal mask for printing and coating the solder (cream solder) to the solder bonding portion including the solder bonding face portions 14, 14, and the electrode pads 12, 12, . . . .

Taking a specific example, when a metal mask having a thickness of 150 μm is used, the divided opening diameter (W2) is made to be equal to or larger than 0.4 mm suitable for solder printing and for forming the metal mask, and the divided width (W1) is made to be equal to or larger than 0.15 mm similarly suitable for solder printing and for forming the metal mask. Thus, the amount of supplied solder to the die pattern 3 can pertinently be restrained, and, in a component mounting procedure for solder-bonding the semiconductor component 1 to the component mounting region 11, further highly reliable solder mounting can be carried out. Specifically, it can be expected to attain an effect of restraining a floating-up of the component, and an open failure of the surrounding electrodes due to the floating-up of the component, which result from an excessive amount of supplied solder at the solder bonding faces of the patterns. Further, it can be expected an effect of restraining failures such as adsorption of the component by the spread solder, an inclination of the component due to nonuniformly spread solder, and a short circuit due to lowered height of the mounted component, which result from the excessively small amount of the supplied solder.

FIG. 5 shows a configuration of a printed wiring board according to a second embodiment. This second embodiment is directed to a printed wiring board mounting a packaged QFN in which four corners are chamfered into circular arc shapes. The die pattern (thermal pad), which is provided at center portion of the bottom face surrounded by the external electrodes, and which is provided mainly for the purpose of heat radiation, is also chamfered into circular arc shapes at four corners thereof, correspondingly to the shape of the package.

As shown in FIG. 5, the printed wiring board according to the second embodiment includes a plurality of electrode pads 22, 22, . . . arranged at a peripheral edge portion of the component mounting region 21, an island-shaped pattern (thermal land) 23 provided at a region surrounded by the electrode pads 22, 22, . . . in the component mounting region 21, and a plurality of solder bonding face portions 24, 24, . . . provided by partitioning the region by a coating of a solder resist (SR) in the island shaped pattern 23.

The island shaped pattern 23 is formed into a rectangular shape that has substantially the same size as the die pattern and that is chamfered at corner portions thereof correspondingly to the die pattern. Sixteen pieces of the circular electrode pads 22, 22, . . . are arranged in the island shaped pattern 23 in a form of matrix. Among them, four of the electrode pads 22, 22, arranged at four corners of the island shaped pattern 23 are respectively arranged along a contour of the island shaped pattern 23 such that peripheral edges thereof partially correspond to the contour of the island shaped pattern 23. Sixteen pieces of the electrode pads 22, 22, . . . including the four electrode pads 22, 22, . . . arranged at the four corners are arranged uniformly with respect to the die pattern of the semiconductor component (QFN) mounted on the component mounting region 21.

By arranging the electrode pads 22, 22, . . . as described above, the amount of supplied solder to the die pattern of the semiconductor component mounted on the component mounting region 21 can pertinently be restrained. Accordingly, an effect similar to that of the first embodiment can be expected. Further, an effect of promoting self alignment in bonding the solder of the semiconductor component can be expected.

FIG. 6 shows a configuration of a main portion of a printed wiring board according to a third embodiment. The printed wiring board according to the third embodiment is configured to mount an LGA and includes a plurality of electrode pads 32, 32, . . . arranged at a peripheral edge portion of the component mounting region 31, an island shaped pattern (thermal land) 33 provided at a region surrounded by the electrode pads 32, 32, . . . at in the component mounting region 31, and a plurality of solder bonding face portions 34, 34, . . . provided by partitioning a region by a coating of a solder resist (SR) at the island shaped pattern 33.

The island shaped pattern 33 is formed in a rectangular shape having a size substantially the same as that of the above-described die pattern, and the electrode pads 32, 32, . . . formed in a quadrangular shape are disposed respectively at four corners of the island shaped pattern 33. The four electrode pads 32, 32, . . . are arranged to be along a contour of the island shaped pattern 33 such that two sides thereof coincide with the corner portion of the island shaped pattern 33. Four of the electrode pads 32, 32, . . . arranged at the four corners respectively have equivalent bonding areas to the die pattern of the semiconductor component (QFN) mounted to the component mounting region 31 and are arranged uniformly thereto.

By having the arrangement of the electrode pads 32, 32 . . . as described above, an amount of supplying the solder to the die pattern of the semiconductor component mounted to the part mounting region 31 can pertinently be restrained. As such, an effect similar to that of the second embodiment can be expected.

Further, in the above-described respective embodiments, a shape of the island shaped pattern 13, shapes and numbers of pieces of the solder bonding face portions 14, 14, . . . , 24, 24, . . . , 34, 34, . . . and the like are not limited to those illustrated but can variously be modified within ranges that can expect effects of the embodiments. For example, a shape of the solder bonding face portion dividedly arranged by the solder resist (SR) is not limited to the circular shape, or the quadrangular shape but can be formed in an elliptical shape, or a polygonal shape of a hexagonal shape, an octagonal shape or the like, or a lattice shape (a checker board shape).

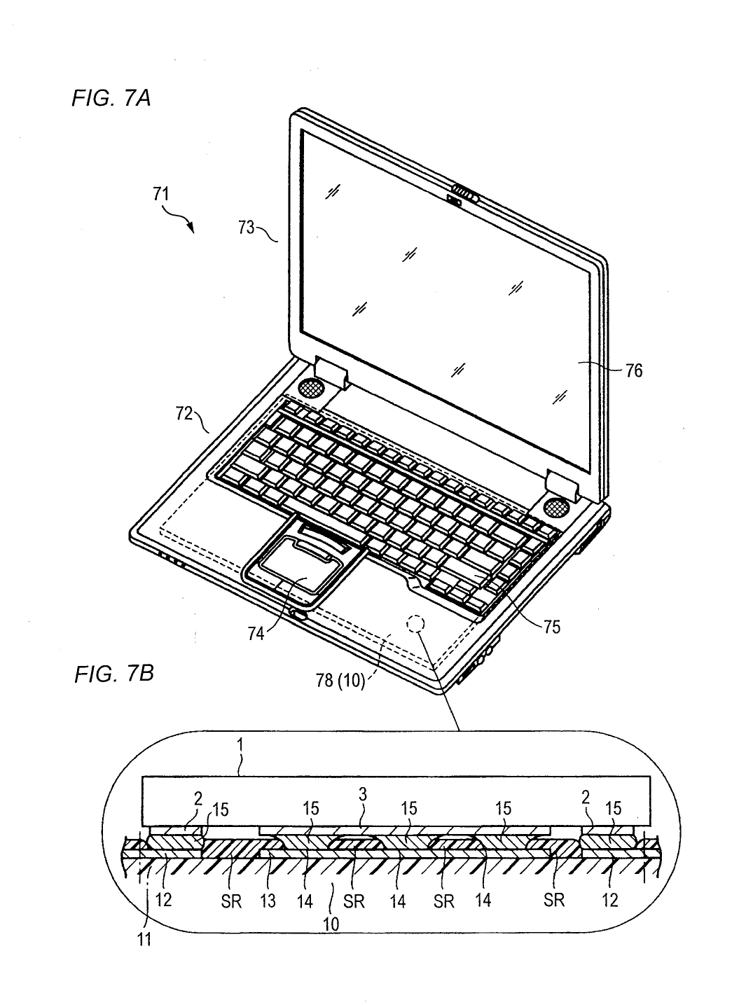

FIG. 7 shows a configuration of an electronic apparatus according to a fourth embodiment. The fourth embodiment includes the electronic apparatus using a printed wiring board shown in FIG. 3 fabricated according to the first embodiment (the printed wiring board mounted with the semiconductor component 1 at the component mounting region 11). FIG. 7 shows an example of applying the printed wiring board 10 according to the first embodiment to a small-sized electronic apparatus of a portable computer of a handy type or the like.

In FIG. 7, a main body 72 of a portable computer 71 is provided with a display portion chassis 73 that is pivotably by way of a hinge mechanism. The main body 72 is provided with operating portions including a pointing device 74, a keyboard 75 and the like. The display portion chassis 73 is provided with a display device 76 of, for example, an LCD or the like.

Further, the main body 72 is provided with a circuit board (mother board) 78 in which a control circuit is installed for controlling the operating portions of the pointing device 74, the keyboard 75 and the like and the display device 76. The circuit board 78 may be realized by using the printed wiring board 10 of the first embodiment shown in FIG. 1 through FIG. 3 mentioned above.

The printed wiring board 10 includes the plurality of electrode pads 12, 12, arranged at a peripheral edge portion of the component mounting region 11, the island shaped pattern (thermal land) 13 provided at the region surrounded by the electrode pads 12, 12, . . . in the component mounting region 11, the plurality of solder bonding face portions 14, 14, . . . provided by partitioning the region by a coating of the solder resist (SR) at the island shaped pattern 13, and the electronic component 1. The electronic component 1 includes the external electrodes 2, 2, . . . at the peripheral edge portion of the bottom face, and the die pattern 3 at the center portion of the bottom face surrounded by the external electrodes 2, 2, . . . . The external electrodes 2, 2, . . . are bonded to the electrode pads 12, 12, . . . by the solder. A portion of the die pattern 3 is bonded to the solder bonding face portions 14, 14, . . . by the solder. Thus, the electronic component 1 is mounted to the component mounting region 11.

The electrode pads 12, 12, . . . are provided correspondingly to the external electrodes 2, 2, . . . provided at the peripheral edge portion of the bottom face of the semiconductor component 1 mounted to the component mounting region 11. The island shaped pattern 13 is provided correspondingly to the single die pattern 3 that is provided at the center portion of the bottom face of the semiconductor component 1. The solder bonding face portions 14, 14, . . . are arranged uniformly to the die pattern 3 forming the heat radiating path of the semiconductor component 1.

According to the printed wiring board 10 configured as above, the amount of supplied solder to the die pattern 3 of the semiconductor component 1 is pertinently restrained by using the solder bonding face portions 14, 14, . . . dividedly formed by the solder resist (SR). Thus, the semiconductor component 1 mounted to the component mounting region 11 is not inclined, and all of the external electrodes 2, 2, . . . are respectively bonded to the electrode pads 12, 12, . . . with the proper solder amount. By applying the printed wiring board 10 to the circuit board 78 of the computer 71, a highly reliable stable circuit operation can be expected.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A printed wiring board comprising:
a component mounting region;
a plurality of electrode pads arranged at a peripheral edge portion of the component mounting region;
a solder resist film on the component mounting region; and
a plurality of solder bonding faces arranged at a region surrounded by the plurality of electrode pads;
wherein the solder resist film and the plurality of solder bonding faces form a thermal land such that the plurality of solder bonding faces are isolated with each other by the solder resist film.

2. The printed wiring board of claim 1,
wherein the plurality of electrode pads are arranged so as to correspond to external electrodes of an electronic component, the external electrodes provided at a peripheral portion of a bottom face of the electronic component mounted on the component mounting region;
the thermal land is positioned so as to correspond to a single die pattern provided at a center portion of the bottom face of the electronic component mounted on the component mounting region, the single die pattern forming a heat radiating path of the electronic component; and
the plurality of solder bonding faces are uniformly arranged with respect to the die pattern.

3. The printed wiring board of claim 2,
wherein each of the solder bonding faces is formed in an opening portion of the solder-resist film so that an amount of solder of the solder bonding face is adjustable according to an area of the opening portion.

4. The printed wiring board of claim 3,
wherein the solder bonding faces are partitioned by the solder-resist film so that an amount of solder of the respective solder bonding face is adjustable according to an area of the opening portion.

5. The printed wiring board of claim 4,
wherein the thermal land is formed in a rectangular shape that has substantially the same size as the die pattern; and
the solder bonding faces are formed at a number of at least four corners of the rectangular shape.

6. The printed wiring board of claim 5,
wherein the solder bonding faces at the four corners of the rectangular shape have contours that correspond to a contour of the thermal land.

7. A printed wiring board comprising:
an electronic component comprising external electrodes and a die pattern, the external electrodes provided at a peripheral portion of a bottom face of the component, the die pattern provided at a center portion of the bottom face;
a component mounting region on which the electronic component is mounted;
a plurality of electrode pads arranged at a peripheral edge portion of the component mounting region to be soldered to the external electrodes;
a plurality of solder bonding faces arranged at a region surrounded by the plurality of electrode pads; and
a solder resist film on the component mounting region;
wherein the solder resist film and the plurality of solder bonding faces form a thermal land such that the plurality of solder bonding faces are isolated with each other by the solder resist film; and
the die pattern is partially soldered to the plurality of bonding faces.

8. The printed wiring board of claim 6,
wherein the die pattern is connected to the thermal land via the solder bonding faces to form a heat radiating path of the electronic component.

9. An electronic apparatus comprising:
an electronic apparatus main body; and
a circuit board;
wherein the circuit board comprises:
an electronic component comprising external electrodes and a die pattern, the external electrodes provided at a peripheral portion of a bottom face of the component, the die pattern provided at a center portion of the bottom face,
a component mounting region on which the electronic component is mounted;
a plurality of electrode pads arranged at a peripheral edge portion of the component mounting region to be soldered to the external electrodes,
a plurality of solder bonding faces arranged at a region surrounded by the plurality of electrode pads, and
a solder resist film that coats the component mounting region;
the solder resist film and the plurality of solder bonding faces form a thermal land such that the plurality of solder bonding faces are isolated with each other by the solder resist film; and
the die pattern is partially soldered to the plurality of bonding faces.
